(19) United States
(12) Patent Application Publication
(10) Pub. No.: US 2010/0065873 A1
(43) Pub. Date: Mar. 18, 2010

(54) LIGHT-EMITTING DEVICE COMPRISING AN ELASTOMERIC LAYER

(75) Inventors: Rabin Bhattacharya, Eindhoven (NL); Martinus Jacobus Johannes Hack, Eindhoven (NL); Adrianus Sempel, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/532,421

(22) PCT Filed: Mar. 25, 2008
(86) PCT No.: PCT/IB08/51101

§ 371 Date: Sep. 22, 2009

(30) Foreign Application Priority Data
Mar. 29, 2007 (EP) 07105175.9

(51) Int. Cl. H01L 33/00

(52) U.S. Cl. 257/98; 257/99; 257/88; 257/E33.056; 257/E33.075; 257/E33.055

(57) ABSTRACT

A light emitting device (100) is provided, which comprises a substrate (101) accomodating at least one light emitting diode (104) and an elastomeric layer (105) arranged to receive light from the light emitting diode(s) (104). The elastomeric layer (105) comprises phosphors (106), which enhance the output of light from the device (100). The light emitting device (100) is flexible and may be incorporated into a fabric, such as a textile or a plastics. Consequently, a textile product (300) comprising such a device (100) is provided.

### FIELD OF THE INVENTION

The present invention relates to a light emitting device comprising a substrate accomodating at least one light emitting diode and an elastomeric layer arranged to receive light emitted by the light emitting diode(s). The invention also relates to a textile product comprising such a light emitting device.

### BACKGROUND OF THE INVENTION

Semiconductor light emitting devices comprising light emitting diodes (LEDs) are among the most efficient and robust light sources currently available.

Due to their small size, potential energy savings and long life, LEDs have rapidly evolved to become a viable light source for several lighting applications, for example general lighting and backlighting for LCD displays.

Currently, there is an emerging market for flexible light emitting devices. In a flexible light emitting device, one or more LED(s) may be arranged on a substrate having a flexible nature. Such a flexible light emitting device can then be integrated into a fabric, for example a textile or a plastics.

One challenge associated with light emitting devices of the above mentioned kind is to provide an enhanced diffusive light output with a low degree of light losses in a flexible material.

US 2006/0082699 A1 discloses a liquid crystal display (LCD) and a light source, accomodating a number of light management films in between to provide bright and uniform illumination. The arrangement of light management layers includes a diffuser plate and at least one of a brightness enhancing layer and a reflective polarizer. Although, the system described in US 2006/0082699 A1 results in an improved light output intensity, it does not possess a flexible nature and is not suitable for integration into e.g. textiles.

Thus, there is a need in the art to provide an enhanced diffusive light output with a low degree of light losses in a flexible material, for use in e.g. textile applications.

### SUMMARY OF THE INVENTION

It is an object of the present invention to at least partly overcome the above mentioned problems, and to fulfill the need in the art.

Especially it is an object of the present invention to provide a flexible light emitting device which provides an enhanced diffusive light output in a flexible material. The inventors have found that it is possible to improve the light output in a flexible material by applying an elastomeric layer comprising particles of phosphors to a substrate accomodating at least one light emitting diode(s).

Thus, in a first aspect the present invention relates to a light emitting device comprising a substrate on which at least one light emitting diode is accommodated, and an elastomeric layer in which phosphor particles are dispersed.

The substrate has a front surface and an opposing back surface. The elastomeric layer is arranged on the front surface of the substrate to receive light from the light emitting diode(s). Phosphor particles are dispersed within said elastomeric layer.

In a light emitting device of the present invention, light emitted by the LED(s) enters into the elastomeric layer and propagates therein. Upon contact with phosphor particles dispersed within the elastomeric layer, light of a desired wavelength is generated. Accordingly, the phosphor particles improve the output intensity of the light emitting diode(s), resulting in a brighter image.

Light generated by the light emitting diode(s) will eventually emerge from the light emitting device via the elastomeric layer.

In embodiments of the present invention, the substrate on which the light emitting diode(s) is/are accommodated is a flexible substrate which is adapted to be bent in at least one direction. The flexibility of the substrate increases the flexibility of the entire light emitting system, thereby allowing for the integration into a flexible matrix, such as a textile or a plastics.

The elastomeric layer comprises a relatively soft and deformable material having a high flexibility. Moreover, the elastomeric layer protects the light emitting diodes from damage caused by mechanical influence.

For instance, the elastomeric layer comprises a polysiloxane material which is highly flexible and has a high dielectric strength. Preferably, the elastomeric layer comprises polydimethylsiloxane.

The light emitting device may further comprise a heat conductive layer. The heat conductive layer serves as a means by which heat transfer is facilitated out of the light emitting device. The heat conductive layer comprises a material having a high thermal conductivity which enables heat transport from the system to the outside air. To further improve the heat transfer, the heat conductive layer can comprise at least one area portion which extends out of the lateral edges of the substrate. This way, heat is more efficiently transferred to the outside air.

In order to increase the flexibility of the light emitting device, the substrate accommodating the LED(s) may be provided with at least one through substrate opening. The through opening(s) allow for bending the light emitting device in two directions simultaneously, with reduced tensile of compressive stress in the plane of the substrate.

In embodiments, the light emitting device comprises a reflective layer which is arranged to reflect light incident in a backward direction.

The reflective layer will reflect the light in a forward direction such that it will emerge from the elastomeric layer of the device. Thus, light incident on the reflecting layer is recycled back into the light emitting device, resulting in an increased intensity of the light emitted from the device. As a consequence, light is more efficiently utilized.

Furthermore, when the substrate is provided with through substrate opening(s), the reflective layer prevents light from escaping through the opening(s) in the substrate.

In alternative embodiments, the reflective layer and the heat conductive layer is the same. In this embodiment, both leakage of light is prevented and heat transfer is facilitated out of the light emitting device. In such case, the reflective layer comprises a material having a high thermal conductivity.

In preferred embodiments, a protective layer is arranged at the backside of the light emitting device. The protective layer is used to provide support to the substrate, and/or the reflective layer and contributes to the flexibility of the light emitting device.

Preferably, the protective layer is an elastomeric layer which contributes to the flexibility of the entire light emitting device.

In embodiments, the elastomeric layer and the protective layer together form an encapsulation for the light emitting device.

In such embodiments, the light emitting device is very flexible making it especially suitable for use in textile applications.

The light emitting device of the present invention may further comprise a diffusive layer arranged on the top of the elastomeric layer.

The diffusive layer is used to diffuse the light received from the light emitting diode(s), resulting in an increase in the diffusion and uniformity of the emitted light.

Alternatively, the diffusive effect is achieved by integrating diffusive particles in the elastomeric layer.

In such embodiments, the elastomeric layer comprises diffusive particles selected from the group consisting of titanium dioxide, silicide, and polymer blends with different indices of refraction.

In another aspect, the present invention relates to a textile product accomodating at least one of the above described light emitting device.

Incorporating a light emitting device of the present invention in a textile product allows the textile product to become luminous and/or display information, such as messages. Examples of such textile products may be clothing, pillows, carpets, curtains, furnishing fabrics, bed textiles and backpacks.

These and other aspects of the invention will be apparent from and elucidated with reference to the embodiment(s) described hereinafter.

### BRIEF DESCRIPTION OF THE DRAWINGS

FIG. 1 illustrates a schematic diagram of a light emitting device of the present invention.

FIG. 2 illustrates a preferred arrangement of a reflective layer used in a light emitting device of the present invention.

FIG. 3 illustrates an article of clothing comprising a light emitting device of the present invention.

### DETAILED DESCRIPTION OF THE EMBODIMENTS

The present application relates to a light emitting device comprising a substrate accomodating at least one light emitting diode and an elastomeric layer arranged to receive light emitted by the light emitting diode(s). The light emitting device is flexible and may be incorporated into a fabric, such as a textile or a plastics.

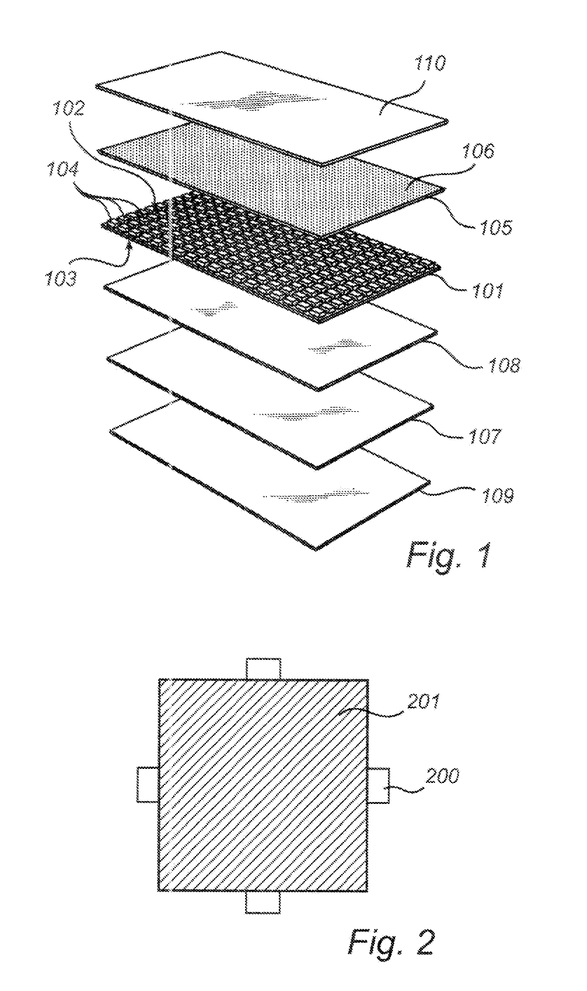

One embodiment of a light emitting device 100 according to the present invention is illustrated in FIG. 1, and comprises a substrate 101 which has a front surface 102 and an opposing back surface 103. The substrate accomodates at least one light emitting diode 104 arranged to emit light in a generally forward direction, i.e. along the normal of the front surface. The light emitting device further comprises an elastomeric layer 105 arranged on the front surface 102 of the substrate 101 to receive light from the light emitting diode(s) 104.

Phosphor particles 106 are dispersed within the elastomeric layer 105.

Light emitted by the LED(s) 104 enters the elastomeric layer 105 and encounters the phosphor particles 106 which are dispersed therein.

The phosphor particles 106 absorb the emitted light at a certain wavelength and emit it at another wavelength. Upon absorption of light, electrons in the material becomes excited to a higher energy level. Upon relaxation back from the higher energy levels, the excess energy is released from the material in form of photons (light).

Also, upon contact with the phosphor particles, the light will be scattered in different directions.

Hence, the integration of phosphors into the elastomeric layer provides an enhanced diffusive light output, and light that emerges from the elastomeric layer 105 will be homogenous and diffuse.

The phosphor particles may for example be selected from the group consisting of YAGs, such as YAG:Ce, YAG:Tb, or YAG:Gd, which work well with blue LEDs.

However, several phosphor materials may be used in the present invention, and these are known to those skilled in the art.

In embodiments of the present invention, the substrate on which the light emitting diode(s) is/are accommodated is a flexible substrate which is adapted to be bent in at least one direction.

The substrate may for example comprise thin plastic sheets or a thin printed circuit board material. Any flexible polymer may be used as the substrate material.

Other materials suitable for flexible substrates are known to those skilled in the art.

The flexibility of the substrate increases the flexibility of the entire light emitting system, thereby allowing for the integration into a flexible matrix, such as a textile or a plastics.

The elastomeric layer preferably comprises a relatively soft and deformable material having a high flexibility. For instance, the elastomeric layer comprises a polysiloxane material which is highly flexible and has a high dielectric strength.

Preferably, the elastomeric layer comprises polydimethylsiloxane.

The elastomeric layer protects the light emitting diodes from damage caused by e.g. mechanical influence.

In embodiments, the light emitting device 100 can further comprise a heat conductive layer 107 arranged to transport heat away from the light emitting diode(s) 104.

The heat conductive layer 107 facilitates heat transfer from the light emitting device to the outside air.

During operation, the LED(s) 104 dissipate heat. At too high temperatures, the LEDs are damaged and emit less light. Hence it is desired to transport the heat away from the LEDs.

The heat conductive layer 107 acts as a means for transporting heat away from the device while being cooled down by the surrounding atmosphere.

The heat conductive layer layer typically comprises a material having a high thermal conductivity, such as, but not limited to, metallic materials, for example copper aluminum, steel etc, and alloys thereof, and other materials such as plastics or ceramic materials having a high thermal conductivity.

The heat conductive layer can be arranged on either the back surface 103 or on the front surface 102 of the substrate 101.

Also, the substrate 101 accomodating the LED(s) 104 can comprise a heat conductive material.

In a preferred embodiment, illustrated in FIG. 2, the heat conductive layer is arranged on the back surface of the substrate 201 and comprises at least one area portion 200 extending out of the lateral edges of the substrate 201.

Heat generated by the LED(s) 104 is transferred to the outside air by means of the area portion(s) 200 of the heat conductive layer 107.

In embodiments, the substrate 101 is provided with at least one through substrate opening (not shown).

The through substrate opening(s) allow for bending the light emitting device in two directions simultaneously, with reduced tensile of compressive stress in the plane of the substrate. Hence, the flexibility of the substrate, and the entire light emitting device is increased.

In embodiments, the through substrate opening(s) may be provided with a cover means that at least partly covers the opening(s).

The cover prevents light emitted from the light emitting diode(s) from escaping through the opening(s) to the back side of the substrate. Hence, the cover means increases the light output without hampering the flexibility of the substrate.

In embodiments, the light emitting device comprises a reflective layer 108, which is arranged to reflect light incident in a backward direction.

Light encountering phosphor particles 106 in the elastomeric layer 105 may be scattered in a backward direction, i.e. in a direction towards the backside of the light emitting device 100. The reflective layer 108 will reflect the light in a forward direction such that it emerges from the elastomeric layer 105 of the device 100.

The reflective layer helps increasing the light output as light is more efficiently utilized.

When the substrate is provided with through substrate opening(s), the reflective layer 108 can be arranged such that the substrate 101 accommodating the LED(s) 104 is sandwiched between the reflective layer 108 and the elastomeric layer 105.

This way, the reflective layer 108 prevents light from escaping through the opening(s) in the substrate 101. Light incident on the reflecting layer is thus recycled back into the light emitting device 100, resulting in an increased intensity of the light emitted through the elastomeric layer 105 of the device 100. As a consequence, light is more efficiently utilized.

The reflective layer 108 may also be arranged on the front surface 102 of the substrate 101. Alternatively, the substrate 101 may comprise a reflective material.

The reflective layer may comprise a material for example selected from the group consisting of metallic materials, such as aluminum, titanium, chromium or nickel. Other suitable reflective materials are known to those skilled in the art.

In embodiments, the reflective layer 108 and the heat conductive layer 107 are the same.

In such embodiments the reflective layer comprises a material having a high thermal conductivity. Hence, both leakage of light is prevented and heat transfer out of the device is facilitated.

The light emitting device may further comprise a protective layer 109 arranged at the backside of the device 100.

The protective layer protects and supports the substrate, and/or the reflective layer and/or the heat conductive layer. Preferably, the protective layer is an elastomeric layer, which contributes to the flexibility of the entire light emitting device.

In embodiments, the elastomeric layer 105 and the protective layer 109 together form an encapsulation for the light emitting device 100. In such an arrangement, the light emitting device is very flexible making it especially suitable for use in textile applications.

When the protective layer 109 and the elastomeric layer 105 form an encapsulation, the area portions 200 typically remain unencapsulated and extend from the encapsulated regions to the outside air, thereby preventing excessive heat generation in the encapsulated components.

In alternative embodiments, the light emitting device 100 comprises at least one diffusive layer 110 arranged on top of the elastomeric layer 105.

Such a diffusive layer comprises diffusive particles for example selected from the group consisting of titanium dioxide, silicide, or polymer blends with differing indices of refraction.

Such particles are transparent and have a refractive index different from the surrounding material, hence when light encounters such diffusive particles, it will be scattered, resulting in a diffuse light output.

The diffusive layer 110 diffuses the light received from the light emitting diode(s) 104, such that the light emitted from the light emitting device 100 is uniform and diffuse.

In alternative embodiments, this diffusive effect is achieved by integrating diffusive particles into the elastomeric layer 105.

The light emitting device 100 of the present invention may be integrated into a textile product. This allows the textile product to become luminous and/or display information, such as messages. Examples of such textile products may be clothing, pillows, carpets, curtains, furnishing fabrics, bed textiles and backpacks.

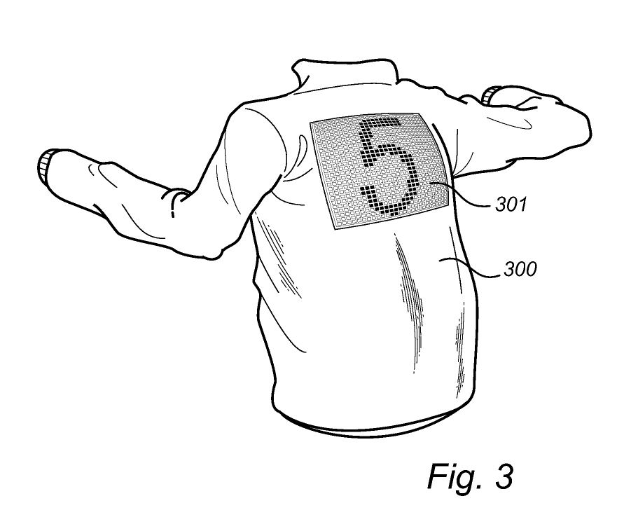

FIG. 3 illustrates a jacket 300 comprising a light emitting device 301 of the present invention.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. For example, the present invention is not limited to the use of a specific type of light emitting diodes. All types of light emitting diodes, including, but not limited to inorganic based LEDs, organic based LEDs (OLED) and polymeric based LEDs (polyLED) can be used.

Typically, the LEDs are adapted to emit light in the visible or near-visible wavelength range, from UV to IR light.

Furthermore, the through substrate opening(s) which may be provided in the substrate is not limited to a specific shape or size, or any specific pattern arrangement.

1. A light emitting device comprising
a flexible substrate bendable in at least one direction and having a front surface and an opposing back surface, said substrate accommodating at least one light emitting diode;
an elastomeric layer comprising phosphor particles dispersed therein and arranged on said front surface of said substrate to receive light emitted by said at least one light emitting diode; and
a heat conductive layer arranged to transport heat away from said at least one light emitting diode.

2. (canceled)

3. A light emitting device according to claim 1, wherein said elastomeric layer comprises a polysiloxane material.

4. A light emitting device according to claim 3, wherein said elastomeric layer comprises polydimethylsiloxane

5. (canceled)

6. A light emitting device according to claim 1, wherein said heat conductive layer comprises at least one area portion extending out of the lateral edges of said substrate.

7. A light emitting device according to claim 1, wherein said substrate defines at least opening therethrough.

8. A light emitting device according to claim 1, further comprising a reflective layer.

9. A light emitting device according to claim 1, wherein said heat conductive layer is configured to reflect light incident thereon.

10. A light emitting device according to claim 1, further comprising a protective layer arranged over the back surface of said substrate.

11. A light emitting device according to claim 10, wherein said protective layer is an elastomeric layer.

12. A light emitting device according to claim 11, wherein said elastomeric layer and said protective layer together form an encapsulation for said device.

13. A light emitting device according to claim 1, which further comprises at least one diffusive layer arranged over said elastomeric layer.

14. A light emitting device according to claim 1, wherein said elastomeric layer further comprises diffusive particles selected from the group consisting of: titanium dioxide, silicide and polymer blends with differing indices of refraction.

15. (canceled)
